(19) United States
(12) Patent Application Publication
(10) Pub. No.: US 2006/0289978 A1
(43) Pub. Date: Dec. 28, 2006

(54) MEMORY ELEMENT CONDUCTING STRUCTURE

(75) Inventor: Shih-Hsiung Lien, Shihlin District, Taipei City (TW)

Correspondence Address: OPTIMUM CARE INTERNATIONAL TECH. INC., P.O. BOX 108-00403, TAIPEI, TW

(73) Assignee: Optinum Care International Tech. Inc, Taipei City (TW)

(21) Appl. No.: 11/379,805

(22) Filed: Apr. 24, 2006

(30) Foreign Application Priority Data
Jun. 24, 2005 (TW) 094210733

(51) Int. Cl. H01L 23/02

(52) U.S. Cl. 257/678

(57) ABSTRACT

Disclosed is a memory element conducting structure, which includes a substrate with contacts, hollow sockets provided at the top side of the substrate corresponding to the contacts of the substrate, conducting media respectively mounted in the hollow sockets and supported on the contacts, and a plurality of positioning means respectively provided in the hollow sockets for holding down a respective memory element against the conducting medium in each hollow socket and the respective contacts of the substrate for enabling a control circuit of the substrate to control the operation of each memory element.

This application claims the priority benefit of Taiwan patent application number 094210733 filed on Jun. 24, 2005.

### BACKGROUND OF THE INVENTION

1. Field of the Invention

The present invention relates generally to memory element conducting arrangements and more particularly, to a memory element conducting structure, which uses positioning means to hold down a memory element in a respective hollow socket against a respective conductive medium and the respective contacts of a substrate for enabling a control circuit of the substrate to control the operation of the memory element.

2. Description of the Related Art

Following fast development of electronic technology, a variety of electronic products have been continuously developed and intensively used in our daily life to improve the living quality. Many electronic products, such as computers, communication devices and etc., use memory means for storing and exchanging data.

After the fabrication of a memory element, the finished memory element must receive a series of electric tests. A memory test machine for examining the electric characteristics of memory modules comprises a test board, which has module slots for receiving memory modules for test. A memory module comprises a plurality of memory elements packed in a package, for example, a TSOP or BAG package.

Further, when examining memory products such as DIMMs (Dual Inline Memory Modules), test conditions equivalent to the actual operation environment of the memory products to be tested must be set up at first. For example, in the actual operation environment of a main memory device for a personal computer, the peripheral apparatus of the computer system (such as CPU, sound card, display card, BIOS, etc.) may affect the input/output functions of the memory module. In order to optimize the test conditions for the memory module to be tested, a main board is used to run the series of tests. However, this memory module examination procedure wastes much time. When an error occurred during the test of one memory module, the memory elements of the memory module must be unsoldered for further examination individually.

In the last 40 years, semiconductor-manufacturing technology has been greatly improved, and the element density in one single chip has been greatly increased. Following the market trend toward relatively smaller size in the fabrication of electronic products, the requirement for manufacturing precision is critical, and improvement in yield rate has become a great challenge. In consequence, the repair work of defective products is frequently encountered in factory. Therefore, it is important how to utilize a modularized method in the fabrication and examination of memory elements, so as to improve the fabrication and examination efficiency to facilitate further repair work.

### SUMMARY OF THE INVENTION

The present invention has been accomplished under the circumstances in view. According to one aspect of the present invention, the memory element conducting structure comprises a substrate, which has a control circuit arranged therein and a plurality of contacts provided at a top side thereof and electrically connected to the control circuit, at least one hollow socket respectively provided at the top side of the substrate corresponding to the contacts of the substrate, each hollow socket defining therein a holding space corresponding to the contacts of the substrate, at least one conductive medium respectively mounted in the at least one hollow socket and pressed on the contacts of the substrate, and at least one positioning means respectively provided in the at least one hollow socket and adapted to hold down a memory element having a plurality of circuit contacts in each of the at least one hollow socket and to impart a downward pressure to the memory element in each of the at least one hollow socket against the conductive medium in each of the at least one hollow socket and the respective contacts of the substrate for enabling the control circuit of the substrate to control the operation of the memory element being set in each of the at least one hollow socket. According to another aspect of the present invention, when one memory element in one hollow socket is tested to be defective, the positioning means at each of the respective hollow socket can conveniently be disengaged from the defective memory element, allowing convenient replacement of repair of the defective memory element.

### BRIEF DESCRIPTION OF THE DRAWINGS

FIG. 1 is an exploded view of a memory element conducting structure according to a first embodiment of the present invention.

FIG. 2 is an elevational view of in an enlarged scaled of a part of the memory element conducting structure according to the first embodiment of the present invention.

FIG. 3 is a schematic sectional view of in an enlarged scaled of a part of the memory element conducting structure according to the first embodiment of the present invention, showing insertion of a memory element into the holding space of the hollow socket.

FIG. 4 corresponds to FIG. 3, showing the springy retaining portions forced outwards.

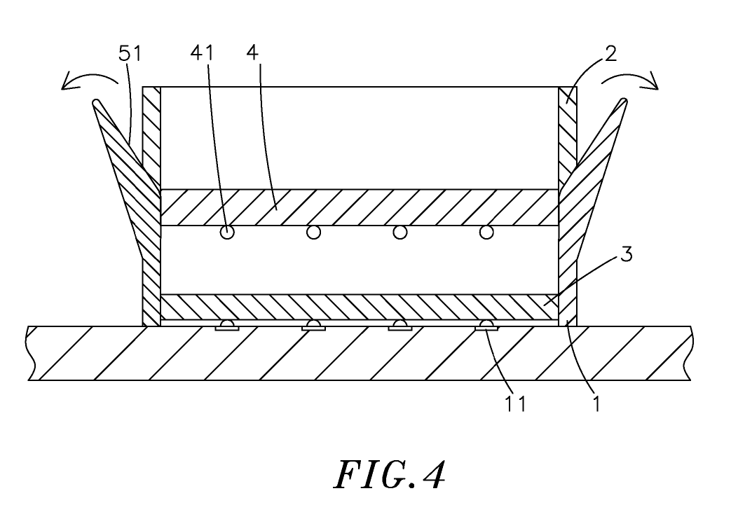

FIG. 5 corresponding to FIG. 4, showing the springy retaining portions returned to their former shape, the memory element set into position.

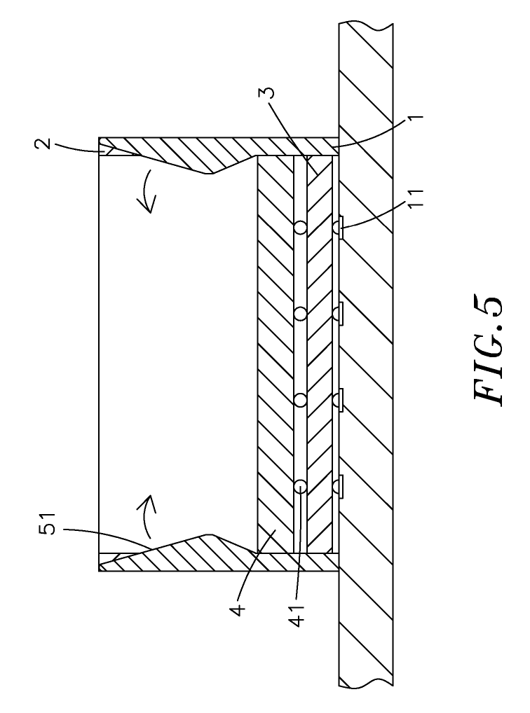

FIG. 6A is an elevational view of a part of a memory element conducting structure according to a second embodiment of the present invention.

FIG. 6B is similar to FIG. 6A but showing a holding-down spring used instead of the protruding portion at the cover plate.

FIG. 6C is similar to FIG. 6A but showing a smoothly curved holding-down wall portion formed in the cover plate instead of the protruding portion.

FIG. 7A is an exploded view of a part of a memory element conducting structure according to a third embodiment of the present invention.

FIG. 7B is similar to FIG. 7A but showing a holding-down spring used instead of the protruding portion at the detachable cover plate.

FIG. 7C is similar to FIG. 7A but showing a smoothly curved holding-down wall portion formed in the detachable cover plate instead of the protruding portion.

FIG. 8A is an exploded view of a part of a memory element conducting structure according to a fourth embodiment of the present invention.

FIG. 8B is a sectional assembly view of FIG. 8A.

FIG. 9 is an elevational view of a part of a memory element conducting structure according to a fifth embodiment of the present invention.

FIG. 10 is a sectional side view of the fifth embodiment of the present invention, showing a memory element held down in the holding space of the hollow socket against the respective conductive medium and the respective contacts of the substrate.

FIG. 11 corresponds to FIG. 10, showing the tool operated, the memory element lifted.

### DETAILED DESCRIPTION OF THE INVENTION

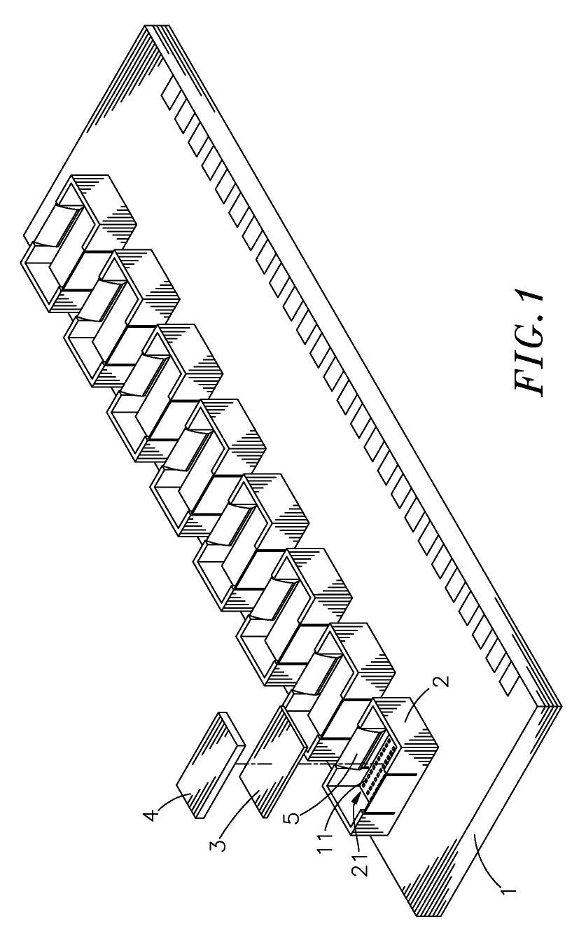

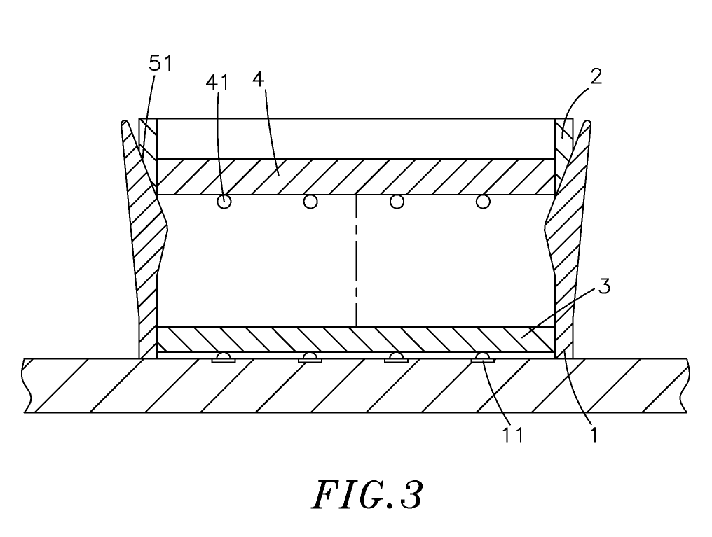

Referring to FIGS. 1 and 3, memory element conducting structure in accordance with the present invention is shown comprising a substrate 1, a plurality of hollow sockets 2 fixedly provided at the top side of the substrate 1, a plurality of conductive media 3 respectively inserted into the hollow sockets 2, and a plurality of positioning means 5 respectively provided inside the hollow sockets 2 for holding a respective memory element 4 in each hollow socket 2 for test.

The substrate 1 has a plurality of contacts 11 and related control circuit arranged therein. The hollow sockets 2 each define a holding space 21 for holding the respective conductive medium 3 and the respective memory element 4. The contacts 11 of the substrate 1 are respectively disposed in the holding space 21 in each of the hollow sockets 2 corresponding to circuit contacts 41 of the memory element 4 in the respective hollow socket 2.

The conductive media 3 are anisotropic conductive films made of resin and conductive powder. The conductive powder is distributed in the resin, having a transmission characteristic subject to the direction of pressure applied thereto. Other materials that form an equivalent structure may be used for the conductive media 3.

The substrate 1 can be a printed circuit board. The circuit contacts 41 of each memory element 4 can be arranged in an array or parallel rows, and respectively formed of a conductive material for transmission of electricity. Other materials that form an equivalent structure may be used for the substrate 1.

During installation, the conductive media 3 are respectively inserted into the holding space 21 in each of the hollow sockets 2 and kept in contact with the respective contacts 11 of the substrate 1 in the respective hollow sockets 2, and then memory elements 4 are respectively inserted into the holding space 21 in each of the hollow sockets 2 and firmly held in position by the respective positioning means 5, keeping the circuit contacts 41 of the memory element 4 pressed on the respective conductive medium 3 against the respective contacts 11 of the substrate 1 in the respective hollow sockets 2. By means of the transmission characteristic of the conductive media 3 subject to the direction of the pressure applied thereto, the circuit contacts 41 of the memory elements 4 are respectively electrically connected to the respective contacts 11 of the substrate 1 in the respective hollow sockets 2, enabling the control circuit of the substrate 1 to control the operation of the memory elements 4.

The hollow sockets 2 can be fixedly fastened to the substrate 1 by any of a variety of techniques. Because this installation procedure is not within the scope of the claims of the present invention, no further detailed description in this regard is necessary.

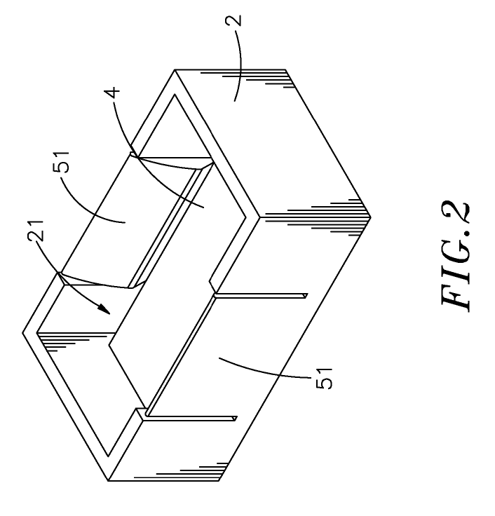

Referring to FIGS. 2˜5, each positioning means 5 comprises two springy retaining portions 51 respectively formed of a part of the respective hollow socket 2 at two opposite lateral sides of the respective holding space 21. The springy retaining portions 51 each have a double-beveled inner wall that slope downwardly outwards and then downwardly inwards. When inserting one memory element 4 into the holding space 21 of one hollow socket 2, the two opposite lateral sides of the memory element 4 are moved downwards over the double-beveled inner walls of the respective springy retaining portions 51 to force the two springy retaining portions 51 outwards, allowing the memory element 4 to pass into the inside of the holding space 21 and into contact with the respective conductive medium 3. After the memory element 4 has been set in position with the respective circuit contacts 41 pressed on the respective conductive medium 3 corresponding to the respective contacts 11 of the substrate 1 in the respective hollow socket 2, the springy retaining portions 51 immediately return to their former shape due to the effect of their material springy power, thereby holding down the memory element 4 firmly in position. When wishing to remove the memory element 4 from the respective hollow socket 2, pull the two springy retaining portions 51 outwards to release the memory element 4 from the constraint of the springy retaining portions 51, and then take the memory element 4 out of the hollow socket 2.

The width of the aforesaid springy retaining portions 51 is determined subject to the size of the conductive media 3 used so as to provide a suitable pressure to the respective memory element 4 and the respective conductive medium 3 in each hollow socket 2.

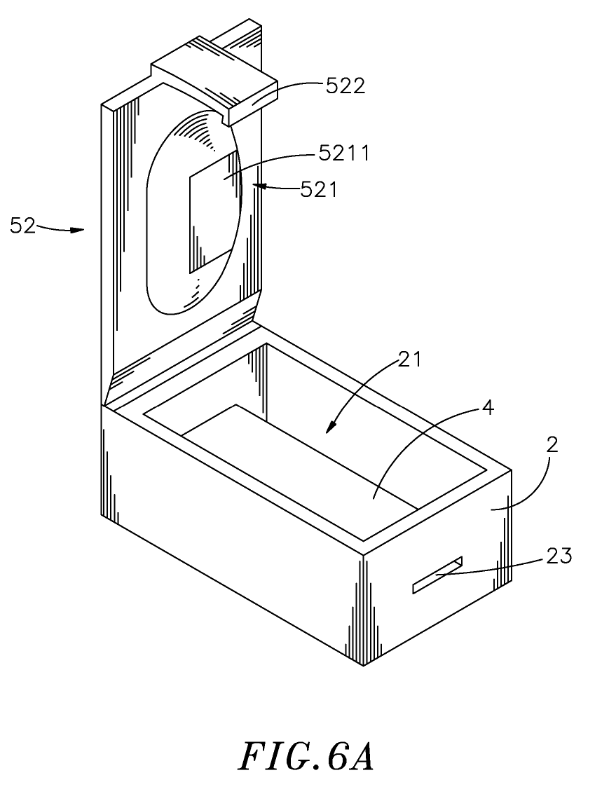

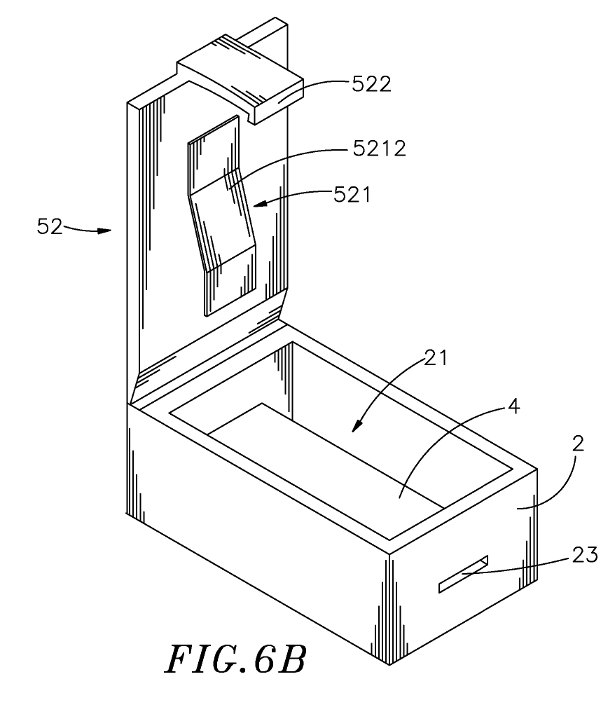

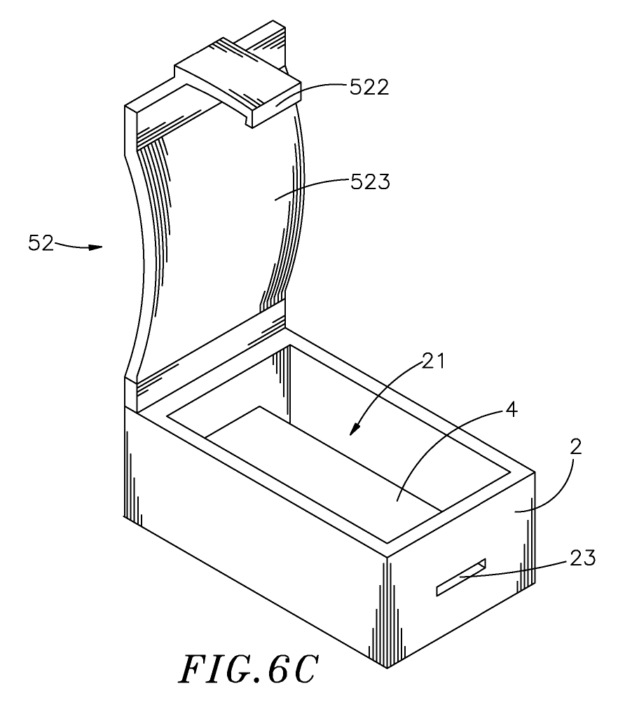

FIGS. 6A˜6C show a second embodiment of the present invention. According to this embodiment, each positioning means 5 comprises a cover plate 52 on the respective hollow socket 2 and adapted to close the holding space 21 of the respective hollow socket 2, a hook 522 extended from one end (the free end) of the cover plate 52 for hooking in a hook hole 23 at the respective hollow socket 2 to lock the cover plate 52 to the respective hollow socket 2 in the closed position, and a holding-down means 521 provided at the inner side of the cover plate 52 for holding down the respective memory element 4 in the holding space 21 of the respective hollow socket 2. The holding-down means 521 can be a protruding portion 5211 projecting from the inner wall of the cover plate 52 as shown in FIG. 6A, a holding-down spring 5212 fixedly mounted on the inner wall of the cover plate 52 as shown in FIG. 6B, or a smoothly curved holding-down wall portion 523 as shown in FIG. 6C. Further, the size of the protruding portion 5211, holding-down spring 5212 or smoothly curved holding-down wall portion 523 is determined subject to the size of the conductive media 3 used, so that a proper downward pressure can be respectively applied to the respective memory element 4 against the respective conductive medium 3.

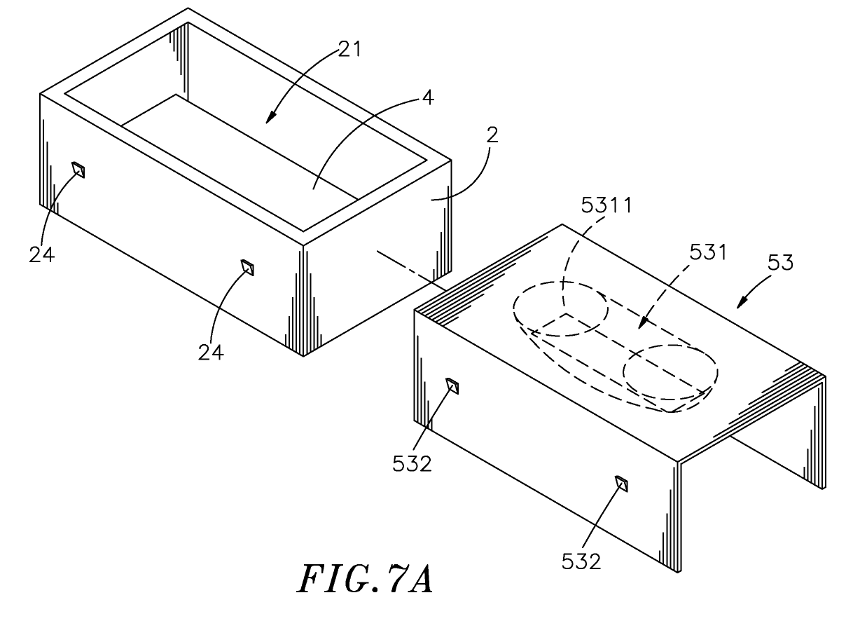

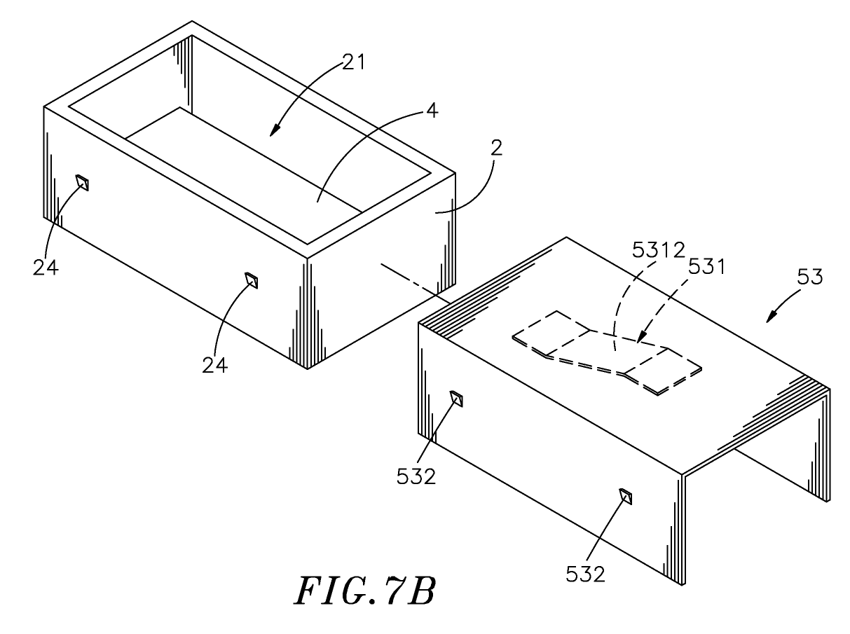

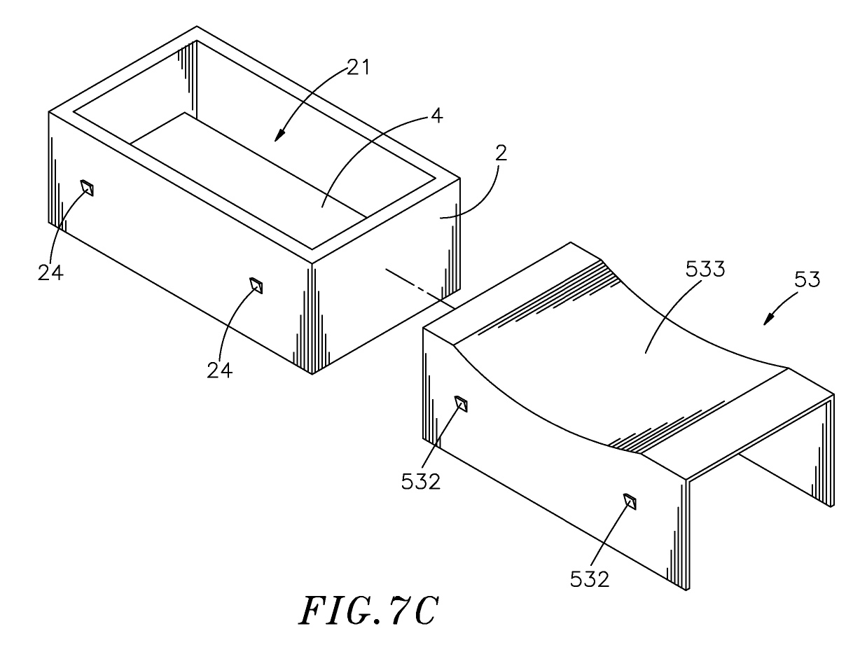

FIGS. 7A˜7C show a third embodiment of the present invention. According to this embodiment, each positioning means 5 comprises a detachable cover plate 53 that is detachably fastened to the respective hollow socket 2 to close the holding space 21, a plurality of male retaining portions 532 provided at the detachable cover plate 53 for engaging into respective retaining holes 24 at the respective hollow socket 2 to lock the detachable cover plate 53 to the respective hollow socket 2, and holding-down means 531 provided at the inner side of the detachable cover plate 53 for holding down the respective memory element 4 in the holding space 21 of the respective hollow socket 2. The holding-down means 531 can be protruding portions 5311 projecting from the inner wall of the detachable cover plate 53 as shown in FIG. 7A, a holding-down spring 5312 fixedly mounted on the inner wall of the detachable cover plate 53 as shown in FIG. 7B, or a smoothly curved holding-down wall portion 533 as shown in FIG. 7C. Further, the size of the protruding portions 5311, holding-down spring 5312 or smoothly curved holding-down wall portion 533 is determined subject to the size of the respective conductive media 3 used, so that a proper downward pressure can be respectively applied to the memory element 4 against the respective conductive medium 3.

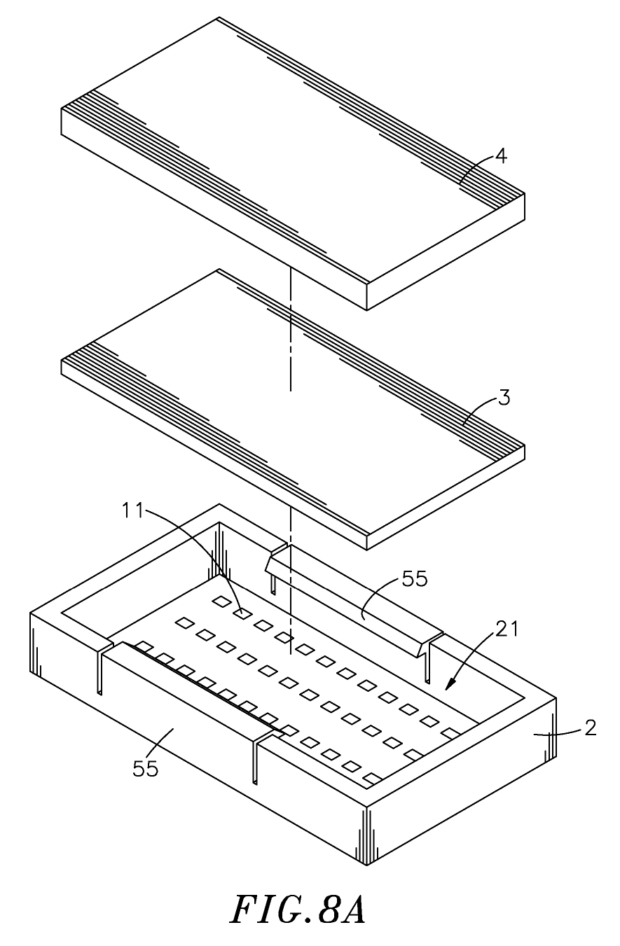

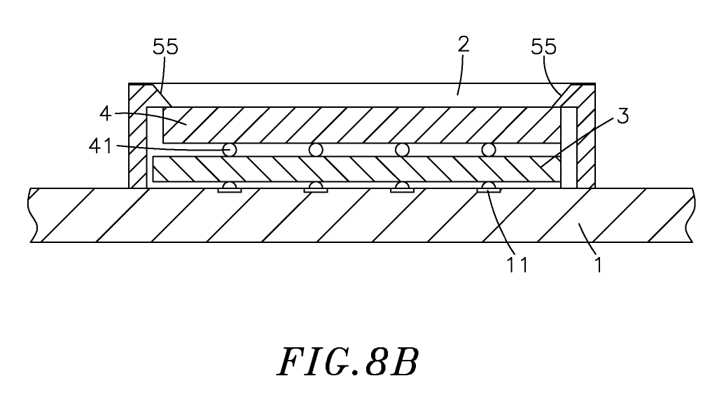

FIGS. 8A and 8B show a fourth embodiment of the present invention. According to this embodiment, each positioning means 5 comprises two springy hooks 55 symmetrically provided at the two opposite lateral sides of the respective hollow socket 2. When inserting the memory element 4 into the holding space 21 of the hollow socket 2, the two springy hooks 55 are respectively forced outwards for allowing the memory element 4 to pass to the bottom side in the holding space 21 of the hollow socket 2. After the memory element 4 has been set into position in close contact with the conducting medium 3 against the contacts 11 of the substrate 1 in the holding space 21 of the respective hollow socket 2, the springy hooks 55 immediately return to their former shape to hook on the top wall of the memory element 4, imparting a downward pressure to the memory element 4 against the conducting medium 3 and the contacts 11 of the substrate 1. When wishing to take the memory element 4 out of the respective hollow socket 2, pull the springy hooks 55 outwards to release the memory element 4 from the constraint of the springy hooks 55, and then remove the memory element 4.

The width of the springy hooks 55 is determined subject to the size of the conductive medium 3 so that a proper pressure can be applied to the memory element 4 against the conductive medium 3 and the contacts 11 of the substrate 1.

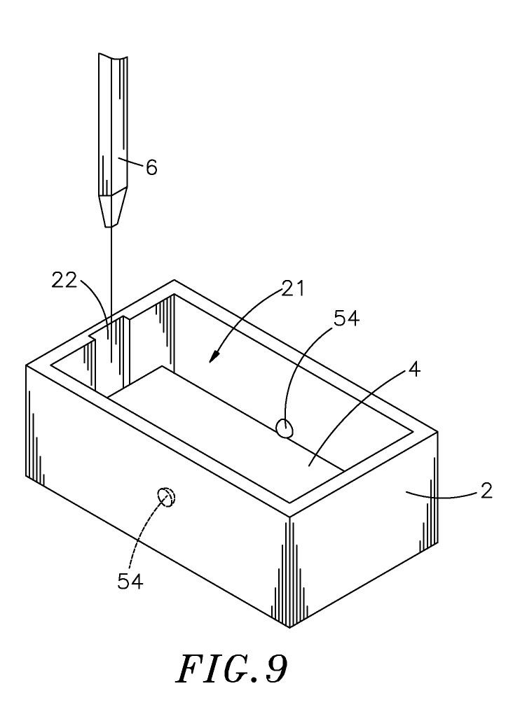

FIG. 9 shows a fifth embodiment of the present invention. According to this embodiment, each positioning means 5 comprises two springy raised portions 54 respectively symmetrically provided at two opposite sides in the holding space 21 of the respective hollow socket 2. During installation of the memory element 4, the memory element 4 is forced downwards over the springy raised portions 54 into close contact with the respective conductive medium 3 against the contacts 11 of the substrate 1 in the holding space 21 of the respective hollow socket 2. At this time, the springy raised portions 54 are respectively stopped at the top wall of the memory element 4, holding down the memory element 4 in position.

The size of the springy raised portions 54 is determined subject to the size of the conductive medium 3 so that a proper downward pressure can be applied to the memory element 4 against the conductive medium 3 at the contacts 11 of the substrate 1.

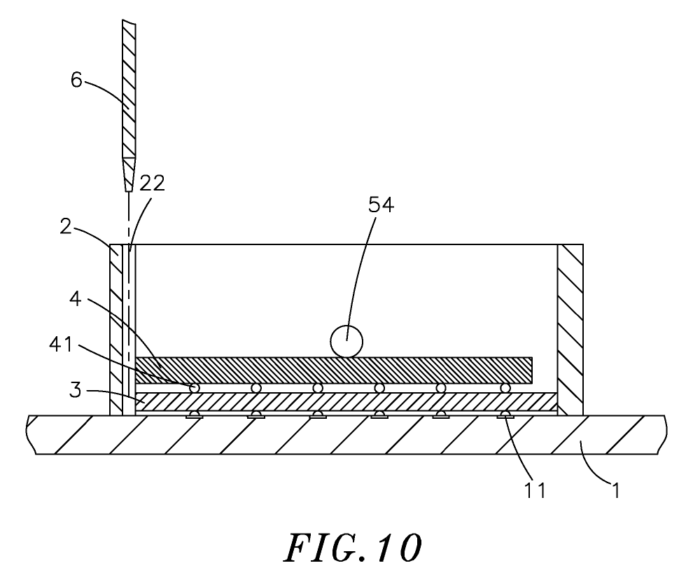

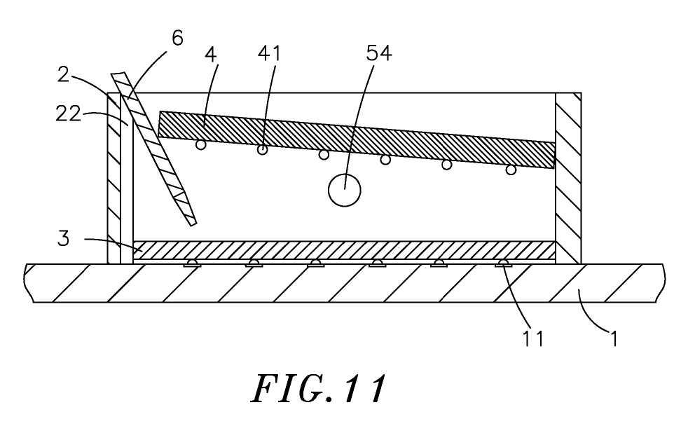

Referring to FIGS. 10 and 11 and FIG. 9 again, the hollow socket 2 has a vertical groove 22 formed in the inside wall thereof at one end of the holding space 21. A tool 6 can be inserted into the vertical groove 22 and turned to prize up the memory element 4 over the springy raised portions 54, so that the memory element 4 can conveniently taken out of the hollow socket 2.

As indicated above, the invention provides a memory element conducting structure, which has the following features:

1. Positioning means is provided in each hollow socket at the substrate to lock the respective memory element and to impart a proper downward pressure to the respective memory element against the respective conductive medium and the respective contacts of the substrate, keeping electric connection between the circuit contacts of the respective memory element and the respective contacts of the substrate so that the control circuit of the substrate can control the operation of each memory element.

2. The invention uses positioning means to hold down memory elements in the holding spaces of the hollow sockets so that the memory elements can quickly be replaced in actual use or test, facilitating the use and test of memory elements and eliminating the drawback of the specific test purpose of the conventional designs.

3. When a defective memory element is found during test, it is not necessary to unsolder the defective memory element, and the defective memory element can directly be removed from the respective hollow socket for replacement or repair when released from the constraint of the positioning means. Therefore, the invention saves much memory, replacement time and further repair cost.

Although a particular embodiment of the invention has been described in detail for purposes of illustration, various modifications and enhancements may be made without departing from the spirit and scope of the invention. For example, oscillator means may be used to atomize water into a fine spray. Accordingly, the invention is not to be limited except as by the appended claims.

What is claimed is:

1. A memory element conducting structure comprising:
a substrate, said substrate having a control circuit arranged therein and a plurality of contacts provided at a top side thereof and electrically connected to said control circuit;
at least one hollow socket respectively provided at the top side of said substrate corresponding to said contacts of said substrate, said at least one hollow socket each defining therein a holding space corresponding to said contacts of said substrate;
at least one conductive medium respectively mounted in said at least one hollow socket and pressed on said contacts of said substrate; and
at least one positioning means respectively provided in each of said at least one hollow socket and adapted to hold down a memory element having a plurality of circuit contacts in each of said at least one hollow socket and to impart a downward pressure to said memory element in each of said at least one hollow socket against said conductive medium in each of said at least one hollow socket and said respective contacts of said substrate for enabling said control circuit of said substrate to control said memory element being set in each of said at least one hollow socket.

2. The memory element conducting structure as claimed in claim 1, wherein said at least one conductive medium each is comprised of an anisotropic conductive film made of a resin and a conductive powder.

3. The memory element conducting structure as claimed in claim 1, wherein said substrate is a printed circuit board.

4. The memory element conducting structure as claimed in claim 1, wherein said at least one positioning means each comprises a pair of springy retaining portions respectively formed of a part of each of said at least one hollow socket at two opposite lateral sides, said springy retaining portions each having a double-beveled inner wall that slope downwardly outwards and then downwardly inwards.

5. The memory element conducting structure as claimed in claim 1, wherein said at least one positioning means each comprises a cover plate on each of said at least one hollow socket to close said holding space of said respective hollow socket.

6. The memory element conducting structure as claimed in claim 5, wherein said cover plate further comprises a holding-down means provided at an inner side thereof for holding down said memory element in each of said at least one hollow socket against said respective conducting medium in said respective hollow socket and said contacts of said substrate in said holding space of said respective hollow socket, and said holding-down means can be a protruding portion or a holding-down spring.

7. The memory element conducting structure as claimed in claim 5, wherein said cover plate comprises a smoothly curved holding-down wall portion for holding down said memory element in each of said at least one hollow socket against said respective conducting medium in said respective hollow socket and said contacts of said substrate in said holding space of said respective hollow socket.

8. The memory element conducting structure as claimed in claim 1, wherein said at least one positioning means each comprises a detachable cover plate detachably fastened to each of said at least one hollow socket to close said holding space of said respective hollow socket.

9. The memory element conducting structure as claimed in claim 8, wherein said detachable cover plate further comprises a holding-down means provided at an inner side thereof for holding down said memory element in each of said at least one hollow socket against said respective conducting medium in said respective hollow socket and said contacts of said substrate in said holding space of said respective hollow socket, and said holding-down means can be protruding portions or a holding-down spring.

10. The memory element conducting structure as claimed in claim 8, wherein said detachable cover plate comprises a smoothly curved holding-down wall portion for holding down said memory element in each of said at least one hollow socket against said respective conducting medium in said respective hollow socket and said contacts of said substrate in said holding space of said respective hollow socket.

11. The memory element conducting structure as claimed in claim 1, wherein said at least one positioning means each comprises two springy raised portions respectively symmetrically provided at two sides of said holding space of each of said at least one hollow socket.

12. The memory element conducting structure as claimed in claim 1, wherein said at least one positioning means each comprises two springy hooks respectively symmetrically provided at two sides of said holding space of each of said at least one hollow socket.

13. The memory element conducting structure as claimed in claim 1, wherein said at least one hollow socket each has a vertical groove for the insertion of a tool to prize up said loaded memory element in said respective hollow socket and to release said memory element from the constraint of said respective positioning means.

14. The memory element conducting structure as claimed in claim 1, wherein said contacts of said substrate are arranged in at least one array corresponding to said holding space of each of said at least one hollow socket.

15. The memory element conducting structure as claimed in claim 1, wherein said contacts of said substrate are arranged in rows corresponding to said holding space of each of said at least one hollow socket.
